(19) United States
(12) Patent Application Publication
(10) Pub. No.: US 2013/0209701 A1
(43) Pub. Date: Aug. 15, 2013

(54) METHOD OF PREPARING SAMPLE FOR TEM OBSERVATION

(71) Applicant: HITACHI HIGH-TECH SCIENCE CORPORATION, (US)

(72) Inventor: Hidekazu SUZUKI, Tokyo (JP)

(73) Assignee: HITACHI HIGH-TECH SCIENCE CORPORATION, Tokyo (JP)

(21) Appl. No.: 13/761,392

(22) Filed: Feb. 7, 2013

(30) Foreign Application Priority Data
Feb. 10, 2012 (JP) 2012-027691

(51) Int. Cl. C23C 16/48

(52) U.S. Cl. CPC C23C 16/486
USPC 427/534

(57) ABSTRACT

Provided is a method of preparing a sample for TEM observation, including: supplying deposition gas to a cross-section of a lamellar portion having exposed recesses and irradiating a deposition film forming region of the cross-section including the recesses with an electron beam, thereby forming a deposition film; irradiating the deposition film with an ion beam, thereby removing a deposition film formed on the cross-section; and irradiating the lamellar portion with the ion beam, thereby thinning the lamellar portion.

This application claims priority from Japanese Patent Application No. 2012-027691 filed on Feb. 10, 2012, the entire subject-matter of which is incorporated herein by reference.

### BACKGROUND OF THE INVENTION

1. Field of the Invention

The present invention relates to a transmission electron microscope (TEM) observation sample preparation method for preparing a sample for TEM observation by using a focused ion beam.

2. Description of the Related Art

Transmission electron microscope (TEM) observation has been known as a method of observing a micro region in a sample for analysis of defects in a semiconductor device or other purposes. In TEM observation, as sample preparation for acquiring a transmission electron image, it is necessary to process a sample so as to have such a thickness that allows an electron beam to transmit therethrough, thereby preparing a thin film sample.

As a method of preparing a thin film sample, a thin film sample preparation method using a focused ion beam is used. In this method, a peripheral portion of a sample is subjected to etching processing so that a portion including a desired observation region inside the sample may be left. Then, the remaining portion is subjected to etching processing until the remaining portion has such a thickness that allows an electron beam to transmit therethrough, to thereby form a thin film sample. In this manner, a thin film sample can be prepared with pinpoint accuracy with regard to the portion including the desired observation region.

In recent years, sizes of the device structure and defects as observation targets become smaller. Accordingly, in TEM observation, in order to observe only the observation target accurately, a thin film sample having a small thickness is necessary. However, there has been a problem in that, if thinning processing is performed for reducing the thickness, a thin film portion is bent and curved.

As a method for solving the problem, there is disclosed an apparatus for automatically recognizing a curvature phenomenon that occurs in thinning processing from an observation image and, when curvature occurs, suspends the thinning processing and performs cutting processing to correct the curvature (see JP-A-2004-361138). According to this method, a thin sample for TEM observation can be prepared by using a focused ion beam.

In the above-mentioned related-art apparatus, however, when a pore such as a recess or a through hole is present inside a thin film sample as an observation target, the pore may be enlarged by thinning processing or there may occur a curtain effect that a step is generated by a difference in etching rate between the pore and its vicinity. Due to this, TEM observation may not be performed accurately.

### SUMMARY OF THE INVENTION

Illustrative aspects of the present invention provide a TEM observation sample preparation method capable of preparing a thin sample for TEM observation by performing thinning processing even in a case where a lamellar sample has a pore.

According to one illustrative aspect of the present invention, there is provided a method of preparing a sample for TEM observation, including: supplying deposition gas to a cross-section of a sample piece having an exposed pore and irradiating a region of the cross-section including the exposed pore with a charged particle beam, thereby forming a deposition film; irradiating the deposition film with a focused ion beam, thereby removing a deposition film formed on the cross-section; and irradiating the sample piece with the focused ion beam, thereby thinning the sample piece.

With this configuration, a part or whole of the pore can be filled with the deposition film, and hence the pore can be prevented from being enlarged or the curtain effect can be prevented from occurring during the thinning processing.

Further, the lamellar sample is thinned after the deposition film is formed, and hence the lamellar sample can be prevented from being curved because of a tension of the deposition film.

In the method of preparing a sample for TEM observation according to the present invention, a thin sample for TEM observation can be prepared by thinning processing even when the thin sample is a lamellar sample having a pore.

### BRIEF DESCRIPTION OF THE DRAWINGS

In the accompanying drawings:

FIG. 1 is a configuration diagram of a charged particle beam apparatus according to an embodiment of the present invention;

FIGS. 2A to 2C are explanatory diagrams of thin film sample preparation according to the embodiment of the present invention;

FIGS. 3A to 3F are explanatory diagrams of the thin film sample preparation according to the embodiment of the present invention;

FIGS. 4A and 4B are explanatory diagrams of the thin film sample preparation according to the embodiment of the present invention; and

FIG. 5 is a flowchart of the thin film sample preparation according to the embodiment of the present invention.

### DETAILED DESCRIPTION

A method of preparing a sample for TEM observation according to an embodiment of the present invention is described below.

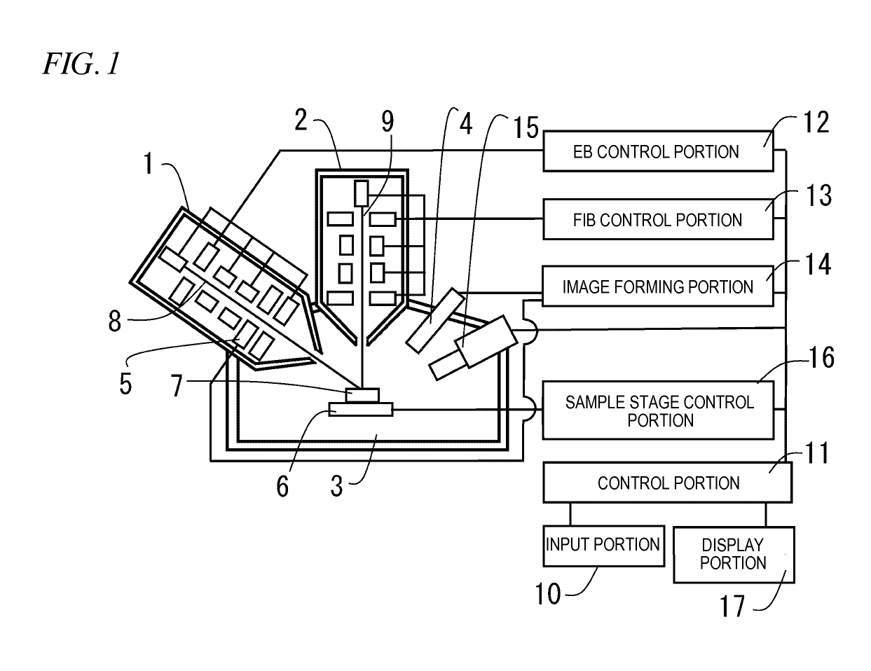

A charged particle beam apparatus for performing the method of preparing a sample for TEM observation is described. As illustrated in FIG. 1, the charged particle beam apparatus includes an EB column 1, a FIB column 2, and a sample chamber 3. The EB column 1 and the FIB column 2 irradiate a sample 7 accommodated in the sample chamber 3 with an electron beam 8 and an ion beam 9, respectively.

The charged particle beam apparatus further includes a secondary electron detector 4 and a backscattered electron detector 5 as charged particle detectors. The secondary electron detector 4 is capable of detecting secondary electrons generated from the sample 7 by irradiation of the electron beam 8 or the ion beam 9. The backscattered electron detector 5 is provided inside the EB column 1. The backscattered electron detector 5 is capable of detecting backscattered electrons reflected by the sample 7 as a result of the irradiation of the electron beam 8 to the sample 7.

The charged particle beam apparatus further includes a sample stage 6 for placing the sample 7 thereon. The sample stage 6 can be tilted to change incident angles of the electron beam 8 and the ion beam 9 to the sample 7. The movement of the sample stage 6 is controlled by a sample stage control portion 16.

The charged particle beam apparatus further includes an EB control portion 12, a FIB control portion 13, an image forming portion 14, and a display portion 17. The EB control portion 12 transmits an irradiation signal to the EB column 1 to control the EB column 1 to radiate the electron beam 8. The FIB control portion 13 transmits an irradiation signal to the FIB column 2 to control the FIB column 2 to radiate the ion beam 9. The image forming portion 14 forms a backscattered electron image based on a signal for scanning the electron beam 8 sent from the EB control portion 12 and a signal of the backscattered electrons detected by the backscattered electron detector 5. The display portion 17 is capable of displaying the backscattered electron image. The image forming portion 14 forms data of a SEM image based on the signal for scanning the electron beam 8 sent from the EB control portion 12 and a signal of the secondary electrons detected by the secondary electron detector 4. The display portion 17 is capable of displaying the SEM image. Further, the image forming portion 14 forms data of a SIM image based on a signal for scanning the ion beam 9 sent from the FIB control portion 13 and a signal of the secondary electrons detected by the secondary electron detector 4. The display portion 17 is capable of displaying the SIM image.

The charged particle beam apparatus further includes a gas gun 15. The gas gun 15 sprays the sample 7 with raw material gas. The sample 7 sprayed with the raw material gas is irradiated with the electron beam 8 or the ion beam 9, to thereby form a deposition film in the irradiated region.

The charged particle beam apparatus further includes an input portion 10 and a control portion 11. An operator inputs conditions on the apparatus control, such as an irradiation condition of the ion beam 9, to the input portion 10. The input portion 10 transmits the input information to the control portion 11. The control portion 11 transmits a control signal to the EB control portion 12, the FIB control portion 13, the image forming portion 14, the gas gun 15, the sample stage control portion 16, or the display portion 17, to thereby control the operation of the charged particle beam apparatus.

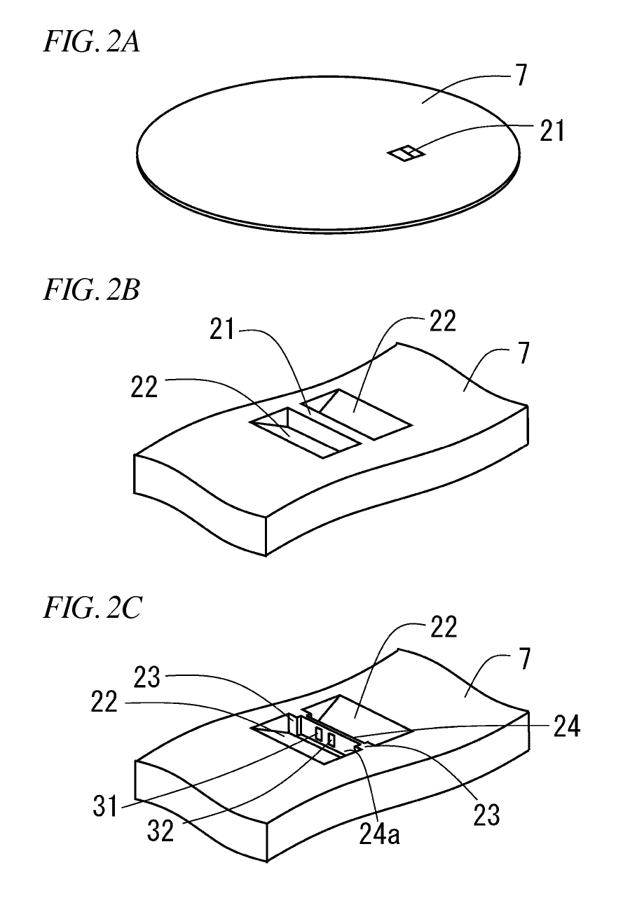

Next, the method of preparing a sample for TEM observation in this embodiment is described. In the method of preparing a sample for TEM observation, as illustrated in FIG. 2A, the sample 7 is partially processed by the ion beam 9, to thereby prepare a lamellar sample 21. FIG. 2B is an enlarged diagram of the lamellar sample and its vicinity. The sample 7 is irradiated with the ion beam 9 to form a processing groove 22 so that the lamellar sample 21 may be left. Further, as illustrated in FIG. 2C, the lamellar sample 21 is processed by the ion beam 9 to be reduced in thickness so as to leave a support portion 23 in the lamellar sample 21, to thereby form a lamellar portion 24. A recess 31 and a recess 32 are exposed in a cross-section 24a of the lamellar portion 24. Next, the lamellar portion 24 and the support portion 23 are cut out from the sample 7 and placed on a sample holder. Alternatively, the lamellar portion 24 and the support portion 23 are not cut out but are subjected to finishing until the lamellar portion 24 becomes thin enough for TEM observation.

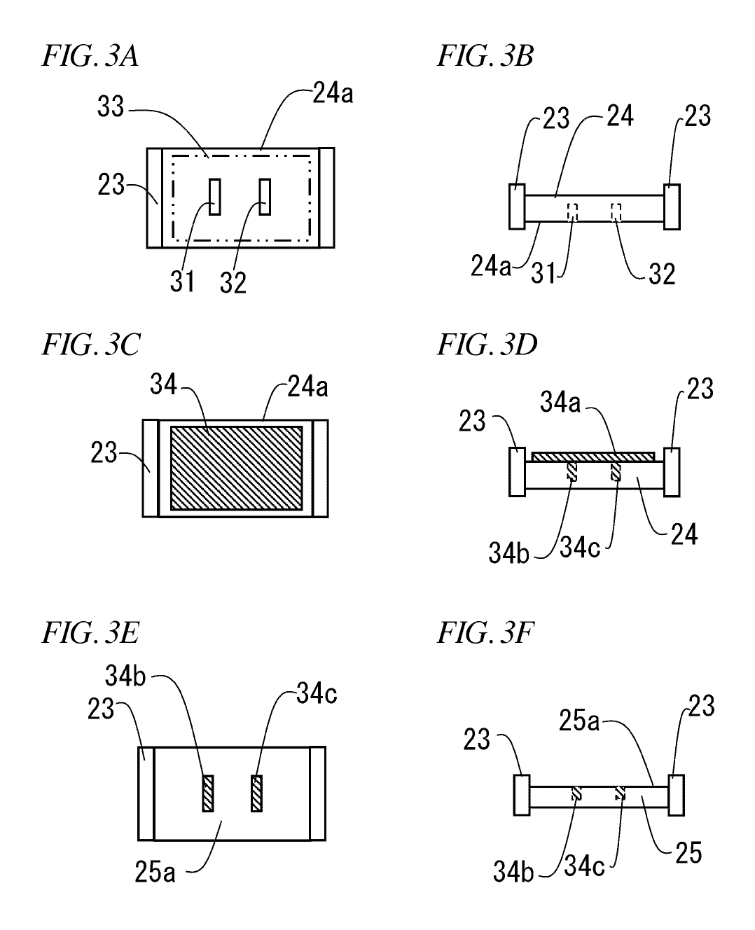

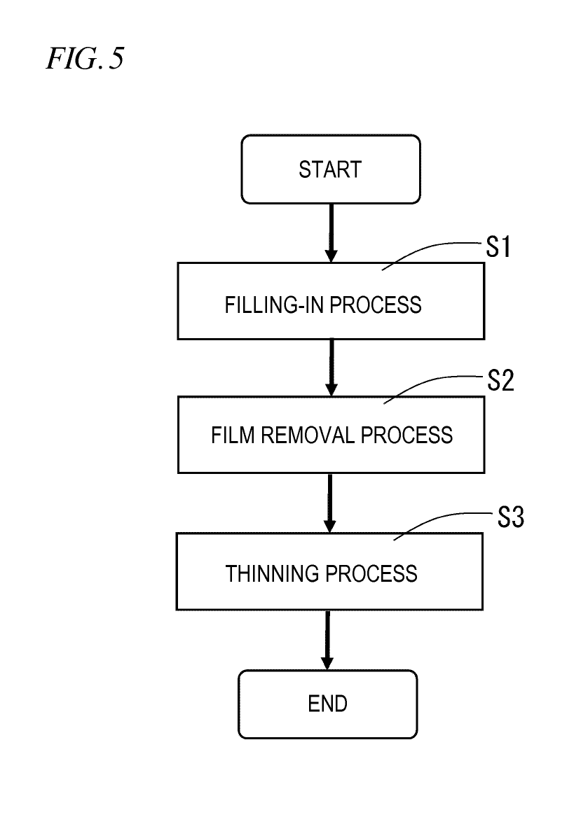

In the finishing, first, a deposition film forming region 33 is set on the cross-section 24a including the recess 31 and the recess 32 as illustrated in FIG. 3A. FIG. 3B is a top view of FIG. 3A. Then, filling-in process S1 in a flowchart of FIG. 5 is performed. In other words, under the state where the lamellar portion 24 is sprayed with carbon-based gas whose main component is carbon, such as naphthalene or phenanthrene, as raw material gas from the gas gun 15, the deposition film forming region 33 is irradiated with the electron beam 8. In this manner, as illustrated in FIG. 3C, a deposition film 34 is formed on the cross-section 24a and formed so as to fill the recess 31 and the recess 32. FIG. 3D is a top view of FIG. 3C. A deposition film 34a is formed on the cross-section 24a, and deposition films 34b and 34c are formed in the recess 31 and the recess 32, respectively.

Although the electron beam 8 is used to form the deposition film 34, the ion beam 9 may be used for preparation instead. However, in the case where the deposition film 34 is formed by the ion beam 9, ion species of the ion beam 9, for example, gallium ions are injected into the inside of the deposition film 34, with the result that a shade thereof may appear in an observation image in TEM observation. Thus, it is preferred to use the electron beam 8.

As the raw material gas, it is also possible to use organic compound gas containing platinum or tungsten. However, in the case of a deposition film whose main component is carbon, a shade thereof does not appear in an observation image in TEM observation. Thus, it is preferred to use raw material gas whose main component is carbon.

Next, film removal processing S2 for removing the deposition film 34a is performed. The deposition film 34 on the cross-section 24a is irradiated with the ion beam 9, to thereby remove the deposition film 34a. The deposition film 34 is scanned and irradiated with the ion beam 9 from a direction substantially perpendicular to the thickness direction of the film forming region 33 so that the scanning direction may be parallel to the cross-section 24a. In this manner, only the deposition film 34a on the cross-section 24a can be removed.

By performing this step, the lamellar portion 24 can be prevented from being curved due to a tension of the deposition film 34 during the next thinning processing S3. If there is no film removal processing S2, that is, if the ion beam 9 is used to perform thinning processing from a surface of the cross-section 24a opposite to the deposition film 34 under the state where the deposition film 34 is provided on the cross-section 24a, the strength of the lamellar portion 24 becomes lower as the thickness of the lamellar portion 24 becomes smaller, with the result that the lamellar portion 24 is curved due to the tension of the deposition film 34. To deal with this problem, the step of removing the deposition film 34 on the cross-section 24a is introduced before thinning processing. In this step, the deposition film 34 is scanned and irradiated with the ion beam 9 from the direction substantially perpendicular to the thickness direction of the film forming region 33 so that the scanning direction may be parallel to the cross-section 24a, and hence the deposition films 34b and 34c formed inside the recesses can be left without etching processing.

Next, the lamellar portion 24 is thinned by the ion beam 9 until the lamellar portion 24 has a desired thickness, to thereby perform thinning processing S3 for forming a thin film portion 25. As illustrated in FIG. 3E, the thin film portion 25 has an exposed cross-section 25a having the deposition films 34b and 34c filling the recesses. FIG. 3F is a top view of FIG. 3E. After the thinning processing, the thickness of the lamellar portion 24 becomes smaller than the thickness of the thin film portion 25. In this manner, a sample for TEM observation having a thickness suitable for TEM observation can be prepared.

The above description is for the preparation of a sample for TEM observation by thinning a lamellar sample having a recess. Next, description is given of thinning processing of a lamellar sample having a through hole instead of a recess.

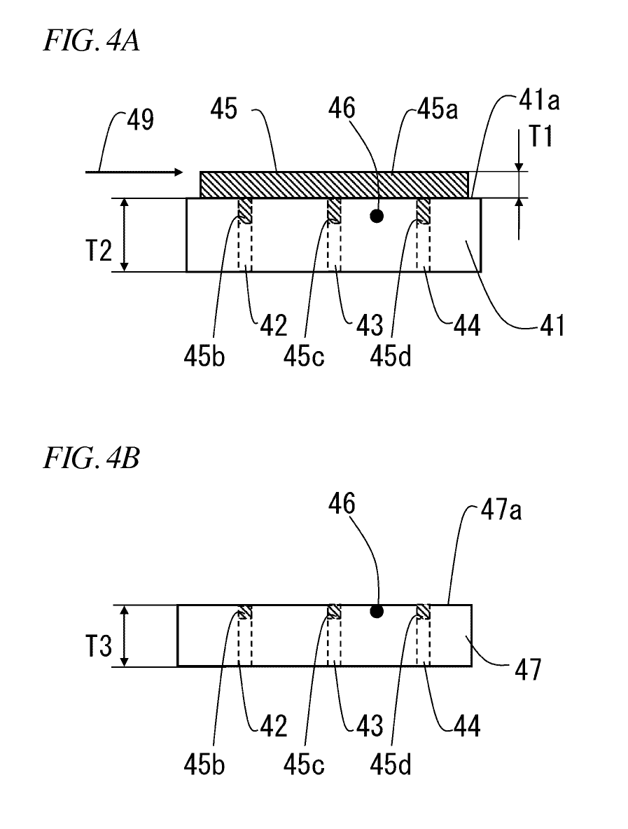

FIG. 4A is an explanatory diagram of a lamellar sample 41 having through holes 42, 43, and 44 and a defect 46 as an observation target. A deposition film 45 is formed by the filling-in process S1. The deposition film 45 includes a deposition film 45a on a cross-section 41a of the lamellar sample 41 and deposition films 45b, 45c, and 45d formed inside the through holes 42, 43, and 44, respectively.

In this case, a thickness T1 of the deposition film 45a is set to be smaller than a thickness T2 of the lamellar sample 41. This is because, if the thickness T1 is larger than the thickness T2, the lamellar sample 41 is curved due to a tension of the deposition film 45a. However, in a case where the filling-in process S1 is performed so as to prevent the thickness T1 of the deposition film 45 from being large (e.g., the filling-in process S1 is performed so that the thickness T1 of the deposition film 45 is less than the thickness T2 of the lamellar sample 41), the through holes 42, 43, and 44 are not completely filled with the deposition films 45b, 45c, and 45d. To deal with this problem, the deposition film 45 is formed on a cross-section close to the defect 46, in this case, on the cross-section 41a. In this manner, the filling-in process S1 is performed on the cross-section close to the observation target, and hence the through holes 42, 43, and 44 can be filled to a depth reaching the observation target.

In the filling-in process S1, a single deposition film 45 is formed so as to cover the through holes 42, 43, and 44 together. This is because, if a deposition film is separately formed for every through hole in the filling-in process S1, a tension of the deposition film is applied locally, with the result that the lamellar sample 41 is curved.

Next, the film removal processing S2 is performed by irradiating the deposition film 45 with the ion beam 9 from an irradiation direction 49 substantially perpendicular to the thickness direction of the deposition film 45, to thereby remove the deposition film 45a.

In addition, the thinning processing S3 is performed by radiating the ion beam 9 from the irradiation direction 49. The thinning processing S3 is finished when the defect 46 appears in a cross-section 47a. Ion beam processing is performed while scanning and irradiating the cross-section 47a with the electron beam 8 to perform SEM observation. Thus, a processing end point can be checked in real time by SEM observation. Therefore, the processing end point can be detected accurately. Note that, backscattered electron image observation may be used instead of SEM observation.

As illustrated in FIG. 4B, the lamellar sample 41 becomes a thin film sample 47 having a thickness T3 smaller than the thickness T2. The thinning processing S3 can be performed within the range where the through holes 42, 43, and 44 are filled with the deposition films 45b, 45c, and 45d, respectively, and hence the enlargement of a pore or the occurrence of the curtain effect can be prevented. In this manner, a thin film sample having a desired observation target exposed in the cross-section can be prepared.

The incident angle of the ion beam 9 does not need to be changed between the film removal processing S2 and the thinning processing S3, and hence the processing can be performed quickly.

What is claimed is:

1. A method of preparing a sample for TEM observation, comprising:
supplying deposition gas to a cross-section of a sample piece having an exposed pore and irradiating a region of the cross-section including the exposed pore with a charged particle beam, thereby forming a deposition film on the cross-section of a sample piece;
irradiating the deposition film with a focused ion beam, thereby removing the deposition film formed on the cross-section; and
irradiating the sample piece with the focused ion beam, thereby thinning the sample piece.

2. The method of preparing a sample for TEM observation according to claim 1,
wherein the sample piece has at least two pores, and
wherein the forming of the deposition film comprises irradiating a region including the at least two pores with the charged particle beam, thereby forming one continuous deposition film on the region.

3. The method of preparing a sample for TEM observation according to claim 1,
wherein the thinning of the sample piece comprises exposing an observation target in a cross-section of the sample piece on a side on which the deposition film is formed.

4. The method of preparing a sample for TEM observation according to claim 1,
wherein the deposition film has a thickness smaller than a thickness of the sample piece.

5. The method of preparing a sample for TEM observation according to claim 1,
wherein the charged particle beam comprises an electron beam.

6. The method of preparing a sample for TEM observation according to claim 1,
wherein the deposition gas comprises carbon-based gas.

7. The method of preparing a sample for TEM observation according to claim 1,
wherein the forming the deposition film comprises filling at least a part of the exposed pore with the deposition film from the cross-section of the sample piece.

8. The method of preparing a sample for TEM observation according to claim 1,
wherein the forming the deposition film comprises filling the exposed pore with the deposition film from the cross-section of the sample piece to a depth greater than a difference of a thickness between before and after the thinning the sample piece.
